(19) United States
(12) Patent Application Publication
(10) Pub. No.: US 2007/0268676 A1
(43) Pub. Date: Nov. 22, 2007

(54) DRIVING CIRCUIT FOR ILLUMINATING AND PROTECTING MULTIPLE DISCHARGE LAMPS WITH TRACE-TO-TRACE CAPACITANCE

(75) Inventor: Shih-Hsien Chang, Taoyuan (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Delta Electronics, Inc., Taoyuan (TW)

(21) Appl. No.: 11/564,404

(22) Filed: Nov. 29, 2006

(30) Foreign Application Priority Data
May 16, 2006 (TW) 095117325

(51) Int. Cl. H05K 1/18

(52) U.S. Cl. 361/763

(57) ABSTRACT

The present invention presents a driving circuit for illuminating multiple discharge lamps. The inventive driving circuit is configured to illuminate multiple discharge lamps by using trace-to-trace capacitances embedded in the circuit board to resonate with the leakage inductance of the transformer, in which the trace-to-trace capacitances are connected to the secondary side of the transformer and respectively connected in series with a discharge lamp. Also, the inventive driving circuit includes a protection device for detecting the currents flowing through multiple discharge lamps by trace-to-trace capacitances, and thereby preventing the multiple discharge lamps from the damages as a result of the current unbalance between the multiple discharge lamps.

### FIELD OF THE INVENTION

The present invention is related to a driving circuit for multiple discharge lamps, and more particularly to a driving circuit for driving and protecting multiple discharge lamps through the use of trace-to-trace capacitance.

### BACKGROUND OF THE INVENTION

Generally speaking, a liquid crystal display requires a backlight module to provide backlighting for illuminating the liquid crystal display. When it is desired to display images on the liquid crystal display, the light source within the backlight module can generate light beams that pass through the case of the backlight module, thereby providing a uniform illumination to the liquid display panel for enabling the liquid crystal display to form the required images. Nowadays, the light source used in the backlight module is implemented by discharge lamps, for example, cold cathode fluorescent lamps. Generally, cold cathode fluorescent lamps are driven by a driving circuit that is configured to provide a high-frequency AC voltage to lamps and includes a feedback control circuit to stabilize lamp currents. In the applications of liquid crystal display, one or more discharge lamps are required to provide sufficient backlighting.

FIG. 1 shows a circuitry of a conventional driving circuit for multiple discharge lamps. The driving circuit of FIG. 1 includes a transformer T having a primary winding Np and a secondary winding Ns, in which the primary winding Np is configured to receive a high-frequency AC voltage and generate a boosted AC voltage across the secondary winding Ns for driving multiple discharge lamps. The transformer T has a leakage inductance Lk, and the driving circuit further includes a plurality of resonant capacitances Cp₁-Cp_{N} connected in parallel with each other and coupled to the secondary side of the transformer T. The leakage inductance Lk respectively resonates with a resonant capacitance and thereby forming a plurality of resonance circuits, which are configured to illuminate multiple discharge lamps Lp₁-Lp_{N}, respectively. Also, each resonant capacitance is connected in series with a discharge lamp and made up of a capacitive element having high impedance, thereby allowing the currents flowing in the discharge lamps Lp₁-Lp_{N} to be approximately equal with each other and achieving current balance among the discharge lamps Lp₁-Lp_{N}.

However, the resonant capacitances Cp₁-Cp_{N} are typically implemented by extrinsic capacitances, which would occupy a considerable area on the circuit board and increase the cost incurred with circuit design. This would cause a waste on the spatial utilization of the circuit board and increase the manufacturing cost.

There is a need to develop a driving circuit for multiple discharge lamps, which is configured to use trace-to-trace capacitance which is intrinsic to the circuit board to drive multiple discharge lamps and protect discharge lamps from being damaged as a result of current unbalance among discharge lamps.

### SUMMARY OF THE INVENTION

An object of the present invention is to provide a driving circuit for driving and protecting multiple discharge lamps, wherein the driving circuit according to the present invention utilizes the leakage inductance of the transformer and the embedded trace-to-trace capacitances of the circuit board to form resonant circuits to drive the multiple discharge lamps.

Another object of the present invention is to provide a driving circuit for driving and protecting multiple discharge lamps, wherein the embedded trace-to-trace capacitance of the circuit board thereof is configured to detect the currents flowing through the discharge lamps and protect the discharge lamps from being damaged as a result of the current unbalance between the discharge lamps.

According to a primitive aspect of the present invention, a driving circuit for illuminating multiple discharge lamps is provided, which includes a circuit board having a plurality of traces disposed thereon for transmitting the control signals for coordinating the operations of the discharge lamps, a transformer mounted on the circuit board and having a primary winding and at least one secondary winding, wherein the primary winding is configured to receive an input AC voltage and the received input AC voltage is converted by the secondary winding into an output AC voltage for illuminating the discharge lamps. The circuit board has a plurality of embedded trace-to-trace capacitances, each of which is connected to the secondary side of the transformer and interconnects adjacent traces. The trace-to-trace capacitances are respectively connected in series with a discharge lamp and resonate with the leakage inductance of the transformer, thereby illuminating the discharge lamps.

Also, the driving circuit further includes a protection device which is made up of a plurality of trace-to-trace capacitances. The trace-to-trace capacitances are respectively connected in parallel with a discharge lamp for detecting the currents flowing through the discharge lamps, thereby protecting the discharge lamps from being damaged as a result of the current unbalance between the discharge lamps.

Now the foregoing and other features and advantages of the present invention will be best understood through the following descriptions with reference to the accompanying drawings, wherein:

### BRIEF DESCRIPTION OF THE DRAWINGS

FIG. 1 is a plan view showing the circuitry of a driving circuit for multiple discharge lamps according to the prior art;

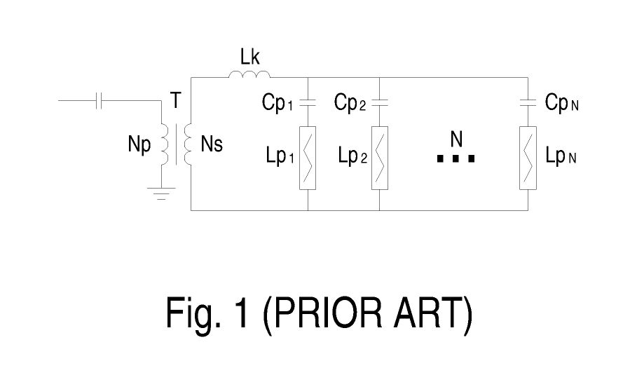

FIG. 2 is a cross-sectional view of a driving circuit for multiple discharge lamps according to a first preferred embodiment of the present invention;

FIGS. 3 (A) and 3(B) are plan views showing the circuitry of a driving circuit for multiple discharge lamps according to a second preferred embodiment of the present invention;

FIG. 4 is a voltage waveform diagram showing the voltage detected at the nodes A, B and detection node D indicated in FIGS. 3(A) and 3(B);

FIG. 5 is a top view of a driving circuit for multiple discharge lamps according to a second preferred embodiment of the present invention; and

FIG. 6 is a top view of a driving circuit for multiple discharge lamps according to a second preferred embodiment of the present invention

### DETAILED DESCRIPTION OF THE PREFERRED EMBODIMENT

Several preferred embodiments embodying the features and advantages of the present invention will be expounded in following paragraphs of descriptions. It is to be realized that the present invention is allowed to have various modification in different respects, all of which are without departing from the scope of the present invention, and the description herein and the drawings are to be taken as illustrative in nature, but not to be taken as limitative.

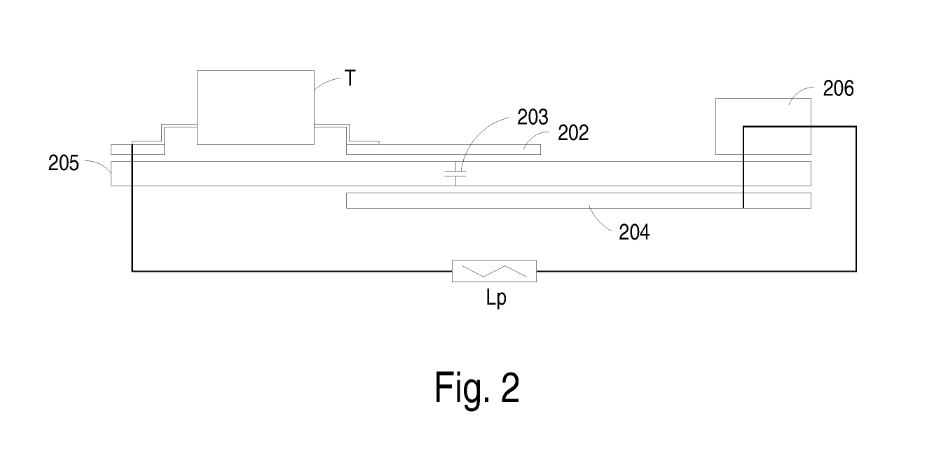

FIG. 2 shows a first preferred embodiment of the present invention. It should be noted that the same reference numeral represents the same elements throughout the specification. In FIG. 2, a driving circuit for multiple discharge lamps according to the present invention is mounted on a printed circuit board 205 which is used as a carrier for the circuitry of the driving circuit. In general, the printed circuit board 205 is provided with numerous traces and voltage reference planes, in which the traces are used to transmit the control signals for coordinating the operations of the discharge lamps. As shown in FIG. 2, a trace-to-trace capacitance 203 is disposed between traces 202 and 204 and embedded in the circuit board 205 with its capacitance value being adjustable according to design requirements. The traces 204 and 206 can transmit the control signals to the discharge lamp Lp through the signal connector 206, and the trace-to-trace capacitance 203 is configured to be connected in series with the discharge lamp Lp. Therefore, the embedded trace-to-trace capacitance 203 of the circuit board 205 can function as the resonant capacitance for driving the discharge lamps and resonate with the leakage inductance of the transformer T, thereby attaining a circuitry for driving multiple discharge lamps.

As to the capacitance value of the trace-to-trace capacitance 203, it can be calculated by the following equation:

$$C = \frac{kA}{d}$$

Where k is the dielectric constant of the dielectric material filled between the traces 202 and 204, A is the minimum overlapping area between the traces 202 and 204, and d is the thickness of the dielectric layer between the traces 202 and 204. Therefore, the capacitance value of the trace-to-trace capacitance 203 can be modified by adjusting the minimum overlapping area or the thickness of the dielectric layer between the traces 202 and 204, and thereby adjusting the impedance of the trace-to-trace capacitance 203.

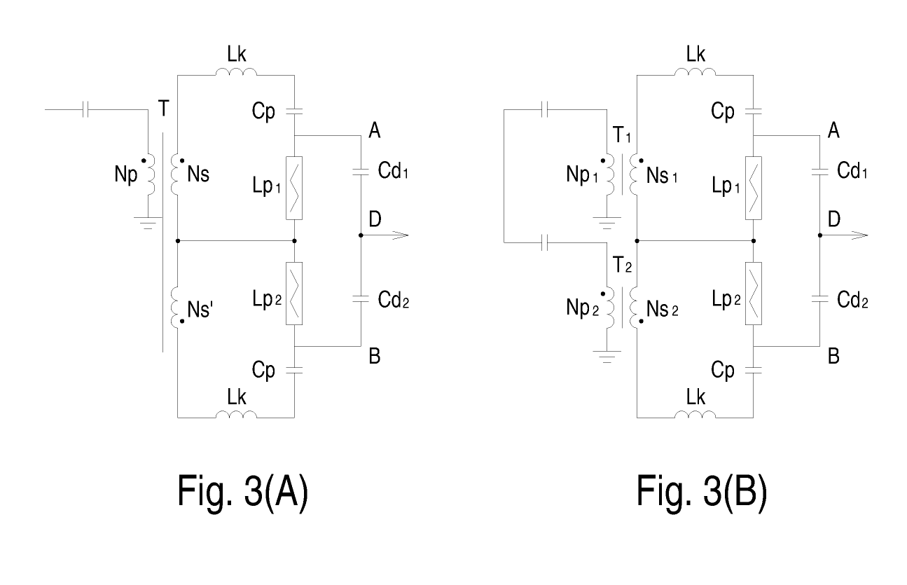

FIG. 3(A) and FIG. 3(B) are circuit diagrams illustrating a second preferred embodiment of the present invention. In FIG. 3(A), the driving circuit includes a transformer T having a primary winding Np and secondary windings Ns, Ns′, in which the secondary windings are respectively coupled with a resonant circuit made up of the leakage inductance Lk of the transformer T and a trace-to-trace capacitance Cp. The trace-to-trace capacitances Cp are respectively connected in series with a discharge lamp (Lp₁, Lp₂), and the discharge lamps Lp₁ and Lp₂ are connected in parallel. Besides, the driving circuit includes a protection circuit which is connected across the discharge lamps Lp₁ and Lp₂ and includes trace-to-trace capacitances Cd₁ and Cd₂. The trace-to-trace capacitances Cd₁ and Cd₂ are connected in parallel with the discharge lamps Lp₁ and Lp₂ and configured to detect the current flowing through the discharge lamps Lp₁ and Lp₂. As shown in FIG. 3(A), the trace-to-trace capacitance Cd₁ is connected in parallel with the discharge lamp Lp₁ and the trace-to-trace capacitance Cd₂ is connected in parallel with the discharge lamp Lp₂, thereby generating a voltage at the node A indicative of the current flowing through the discharge lamp Lp₁ and generating a voltage at the node B indicative of the current flowing through the discharge lamp Lp₂. Because the trace-to-trace capacitance Cd₁ is connected in series with the trace-to-trace capacitance Cd₂ and the detection node D is an intermediate node between the trace-to-trace capacitances Cd₁ and Cd₂, the voltage detected at the detection node D represents the sum of the voltage detected at the node A and the voltage detected at the node B. Therefore, the voltage waveform detected at the detection node D can be used to determine if the current flowing through the discharge lamp Lp₁ is approximately equal to the current flowing through the discharge lamp Lp₂.

In FIG. 3(B), the driving circuit includes two transformers T₁ and T₂ respectively having a primary winding (Np₁, Np₂) and a secondary winding (Ns₁, Ns₂), in which the secondary windings Ns₁ and Ns₂ are respectively coupled with a resonant circuit made up of the leakage inductance Lk of the transformer and a trace-to-trace capacitance Cp. The trace-to-trace capacitances Cp are respectively connected in series with a discharge lamp (Lp₁, Lp₂), and the discharge lamps Lp₁ and Lp₂ are connected in parallel. The trace-to-trace capacitance Cd₁ and Cd₂ that are used to detect the current flowing through the discharge lamps Lp₁ and Lp₂ are respectively connected across a discharge lamp (Lp₁, Lp₂) and connected in series through a detection node D. Therefore, the voltage waveform detected at the detection node D can be used to determine if the current flowing through the discharge lamp Lp₁ is approximately equal to the current flowing through the discharge lamp Lp₂.

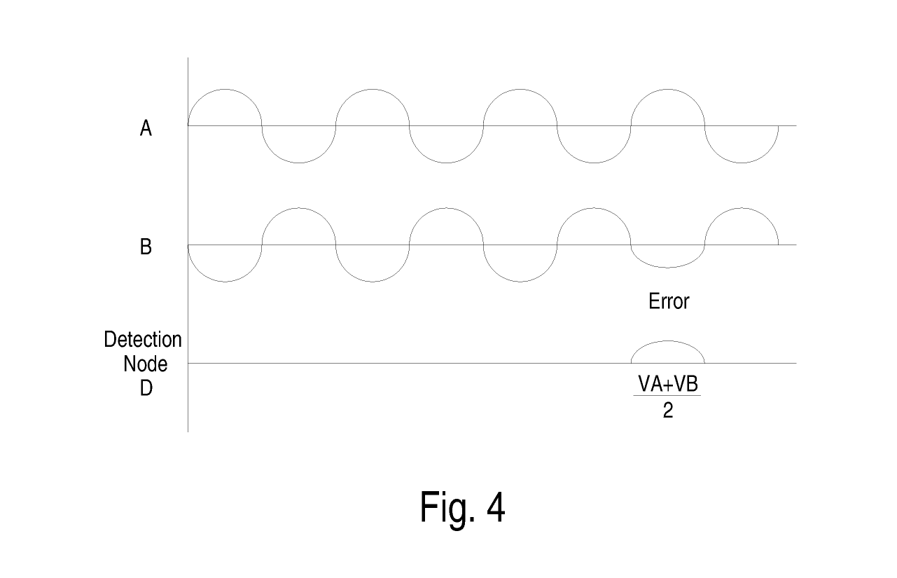

FIG. 4 shows the voltage waveforms of the voltages detected at the nodes A, B, and the detection node D indicated in FIGS. 3(A) and 3(B). As shown in FIG. 4, if the currents flowing through the discharge lamps Lp₁ and Lp₂ are approximately equal with each other, the voltage detected at the node A should be an AC voltage having the same phase with the AC voltage detected at the node B but having a reverse polarity with the AC voltage detected at the node B. Under this condition, the voltage detected at the detection node D should be zero. If the currents flowing through the discharge lamps Lp₁ and Lp₂ are not approximately equal with each other within a certain duty cycle, the amplitude of the voltage detected at the node A and the amplitude of the voltage detected at the node B should be different. Under this condition, the voltage detected at the detection node D can not zeroed and thus the problem of current unbalance between the discharge lamps can not be avoided, as shown in FIG. 4. When the detection node D detects the problem of current unbalance between the discharge lamps, the lamp feedback circuit (not shown) will send an error message to the control circuitry located at the primary side of the transformer so as to shut down the driving circuit, thereby preventing the damages as a result of the current unbalance between the discharge lamps.

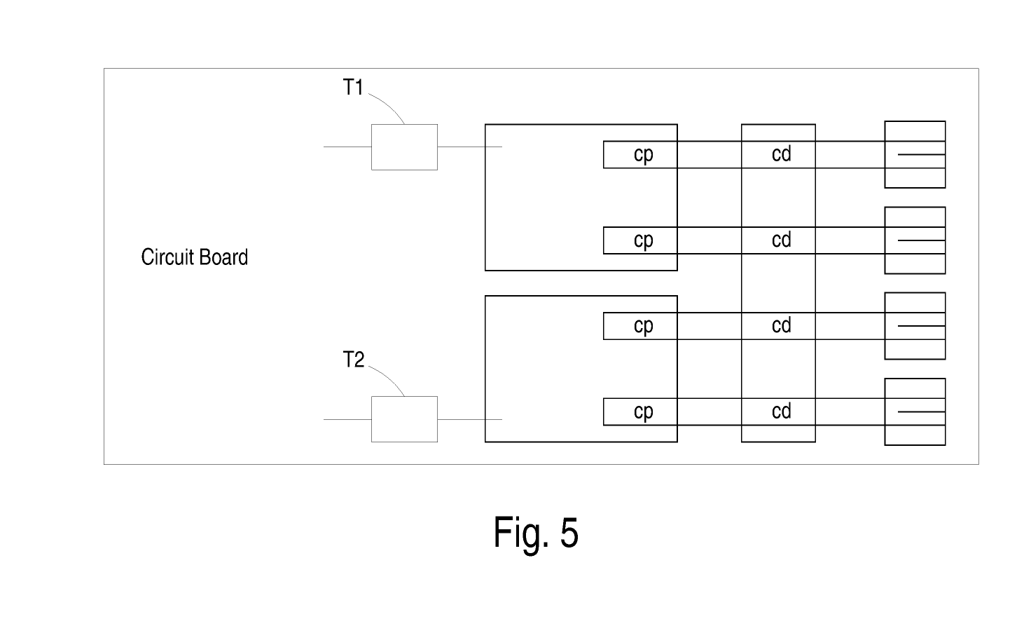

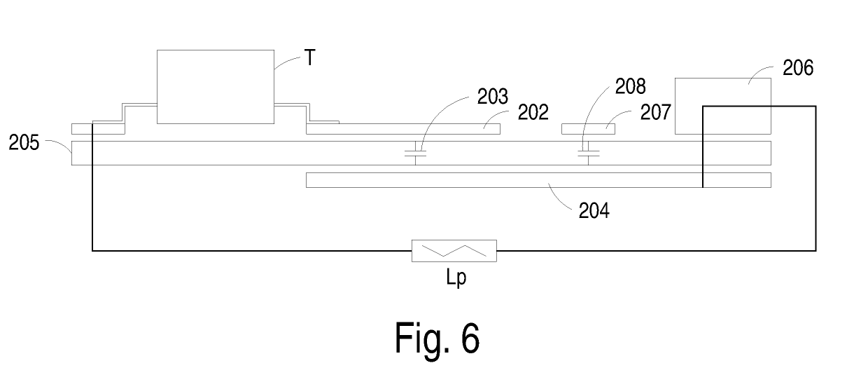

FIG. 5 shows a top view of the driving circuit according to the second preferred embodiment of the present invention, and FIG. 6 shows a cross-sectional view of the driving circuit according to the second preferred embodiment of the present invention. As shown in FIG. 5, a plurality of trace-to-trace capacitances Cp and Cd are respectively connected to the secondary side of the transformer T₁ and the secondary side of the transformer T₂, wherein the transformers T₁ and T₂ are respectively configured to provide a high-frequency AC voltage to drive a plurality of discharge lamps. The trace-to-trace capacitances Cp are respectively connected in series with a discharge lamp and resonate with the leakage inductance of the transformers T₁ and T₂ to illuminate the discharge lamps, and the trace-to-trace capacitances Cd are respectively connected with a trace-to-trace capacitance Cp to detect the currents flowing through the discharge lamps. In FIG. 6, the trace-to-trace capacitance Cp which interconnects the traces 202 and 204 and drives the discharge lamp Lp is denoted with the reference numeral 203, and the trace-to-trace capacitance Cd which interconnects the traces 207 and 204 and detects the current flowing through the discharge lamp Lp is denoted with the reference numeral 208. The traces 202, 204, 207 are configured to transmit the control signals through the signal connector 206 for coordinating the operations of the discharge lamp Lp.

Alternatively, the trace-to-trace capacitances can be connected across the primary side and the secondary side of the transformer, and thus the electrical isolation between the primary side and the secondary side of the transformer can be enhanced. Also, the inventive driving circuit employs the embedded trace-to-trace capacitances which are inherent in the circuit board 205 to be connected in series with the discharge lamps and resonate with the leakage inductance of the transformer. In this manner, the voltage waveform of the output AC voltage generated at the secondary side of the transformer can be modulated into a desired AC voltage waveform for driving the discharge lamps. Therefore, the number of the high-voltage capacitances required in the driving circuit can be greatly reduced, and thereby the space consumption and manufacturing cost of the circuit board can be lowered.

Those of skilled in the art will recognize that these and other modifications can be made within the spirit and scope of the present invention as further defined in the appended claims.

What is claimed is:

1. A driving circuit for illuminating a plurality of discharge lamps, comprising:
a circuit board having a plurality of traces disposed thereon; and
a transformer mounted on the circuit board and having a primary winding and at least one secondary winding, wherein the primary winding is configured to receive an input AC voltage and convert the received AC voltage into an output AC voltage across the at least one secondary winding for illuminating the plurality of discharge lamps;
wherein a plurality of trace-to-trace capacitances are embedded in the circuit board and coupled to the secondary side of the transformer, and wherein each trace-to-trace capacitance is configured to interconnect adjacent traces and the plurality of trace-to-trace capacitances are respectively connected in series with a discharge lamp and resonate with a leakage inductance of the transformer, thereby illuminating the plurality of discharge lamps.

2. The driving circuit for illuminating a plurality of discharge lamps according to claim 1 further comprising a protection circuit connected in parallel with the plurality of discharge lamps for detecting the currents flowing through the plurality of discharge lamps, thereby determining if the currents flowing through the plurality of discharge lamps are approximately equal with each other.

3. The driving circuit for illuminating a plurality of discharge lamps according to claim 2 wherein the protection circuit comprises a plurality of trace-to-trace capacitances.

4. A driving circuit for illuminating a plurality of discharge lamps, comprising:
a circuit board having a plurality of traces disposed thereon;
a transformer mounted on the circuit board and having a primary winding and at least one secondary winding, wherein the primary winding is configured to receive an input AC voltage and convert the received AC voltage into an output AC voltage across the at least one secondary winding for illuminating the plurality of discharge lamps; and
a protection circuit connected in parallel with the plurality of discharge lamps for detecting the currents flowing through the plurality of discharge lamps, thereby determining if the currents flowing through the plurality of discharge lamps are approximately equal with each other;
wherein a plurality of trace-to-trace capacitances are embedded in the circuit board and coupled to the secondary side of the transformer, and wherein each trace-to-trace capacitance is configured to interconnect adjacent traces and the plurality of trace-to-trace capacitances are respectively connected in series with a discharge lamp and resonate with a leakage inductance of the transformer, thereby illuminating the plurality of discharge lamps.

5. The driving circuit for illuminating a plurality of discharge lamps according to claim 4 wherein the protection circuit comprises a plurality of trace-to-trace capacitances.
